(19) United States
(12) Patent Application Publication
(10) Pub. No.: US 2026/0235320 A1
(43) Pub. Date: Aug. 13, 2026

(54) VEHICLE FLUID HEATING DEVICE

(71) Applicant: Panasonic Automotive Systems Co., Ltd., Kanagawa (JP)

(72) Inventors: Ko AKIBA, Shiga (JP); Atsushi HIROTA, Shiga (JP)

(73) Assignee: Panasonic Automotive Systems Co., Ltd., Kanagawa (JP)

(21) Appl. No.: 19/448,684

(22) Filed: Jan. 14, 2026

(30) Foreign Application Priority Data
Feb. 13, 2025 (JP) 2025-021382

(51) Int. Cl. F24H 1/00; F24H 9/00; F24H 15/223; F24H 15/25; F24H 15/31; H05B 1/02

(52) U.S. Cl. CPC F24H 1/009; F24H 9/0015; F24H 15/223; F24H 15/25; F24H 15/31; H05B 1/0244; H05B 2203/021; H05B 2203/035

(57) ABSTRACT

A vehicle fluid heating device includes: a tank that internally includes a flow path that guides a fluid; a heater that is disposed to sandwich the tank and heats the fluid by heating the tank; and at least one control element that controls the heater. The tank includes front and rear surfaces where the heater is disposed, and a side surface different from the front and rear surfaces. The at least one control element is disposed on the side surface of the tank.

### CROSS REFERENCE TO RELATED APPLICATION

The present application is based on and claims priority of Japanese Patent Application No. 2025-021382 filed on Feb. 13, 2025.

### FIELD

The present disclosure relates to vehicle fluid heating devices.

### BACKGROUND

Patent Literature (PTL) 1 discloses a heating element casing that heats a liquid, such as water or a liquid coolant. A vehicle heating device includes a casing for accommodating a heating element. The casing includes a flow path through which a liquid is to flow, and the flow path is partially composed of resin. The heating element casing includes a casing for accommodating the heating element and an air flow path through which air flows.

### CITATION LIST

### Patent Literature

PTL 1: US Patent Application Publication No. 2022/282933

### SUMMARY

The heating element casing in PTL 1 can be improved upon.

In view of this, the present disclosure provides a vehicle fluid heating device capable of improving upon the above related art.

A vehicle fluid heating device according to an aspect of the present disclosure includes: a tank that internally includes a flow path that guides a fluid; a heater that is disposed to sandwich the tank and heats the fluid by heating the tank; and at least one control element that controls the heater, wherein the tank includes front and rear surfaces where the heater is disposed, and a side surface different from the front and rear surfaces, and the at least one control element is disposed on the side surface of the tank.

The vehicle fluid heating device according to the present disclosure is capable of improving upon the above related art.

### BRIEF DESCRIPTION OF DRAWINGS

These and other advantages and features of the present disclosure will become apparent from the following description thereof taken in conjunction with the accompanying drawings that illustrate a specific embodiment of the present disclosure.

FIG. 1A is a perspective view illustrating a vehicle fluid heating device according to an embodiment.

FIG. 1B is another perspective view illustrating the vehicle fluid heating device according to the embodiment.

FIG. 2 is a block diagram illustrating the vehicle fluid heating device according to the embodiment.

FIG. 3 is a plan view illustrating a flow path and a heater of the vehicle fluid heating device.

FIG. 4 is another plan view illustrating the flow path and the heater of the vehicle fluid heating device.

FIG. 5 is a plan view illustrating a first flow path, a second flow path, a third flow path, and the heater of the vehicle fluid heating device.

FIG. 6A is another plan view illustrating the first flow path, the second flow path, the third flow path, and the heater of the vehicle fluid heating device.

FIG. 6B is a plan view illustrating the first flow path, the second flow path, the third flow path, and the heater of the vehicle fluid heating device including a controller and a valve.

FIG. 7 is a plan view illustrating the first flow path, the second flow path, the third flow path, and the heater of the vehicle fluid heating device having a cavity.

FIG. 8 is another plan view illustrating the first flow path, the second flow path, the third flow path, and the heater of the vehicle fluid heating device having the cavity.

FIG. 9 is a plan view illustrating the vehicle fluid heating device including a temperature detector disposed at a tank.

### DESCRIPTION OF EMBODIMENT

An embodiment will be described in detail below with reference to the drawings.

The embodiment to be described below is a comprehensive or specific example. Numerical values, shapes, materials, components, positions and connection methods of the components and so on indicated in the embodiment below are examples, and are not intended to limit the present disclosure. Among the components in the embodiment below, components not indicated in the independent claim are described as optional components.

Each drawing is a schematic view and is not necessarily a precise illustration. Identical components in the drawings are given the same reference signs.

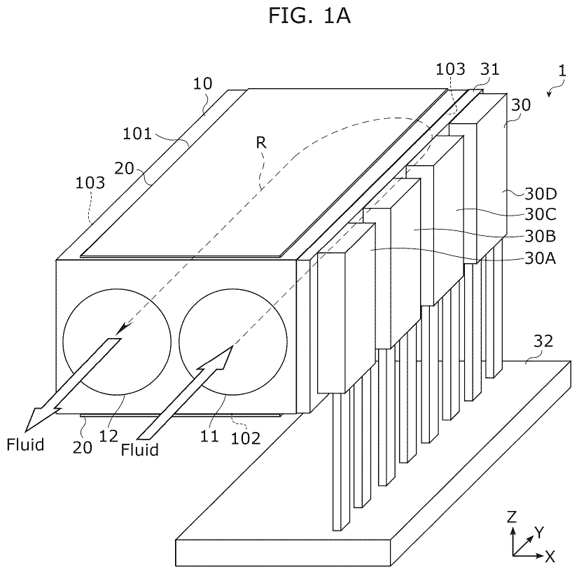

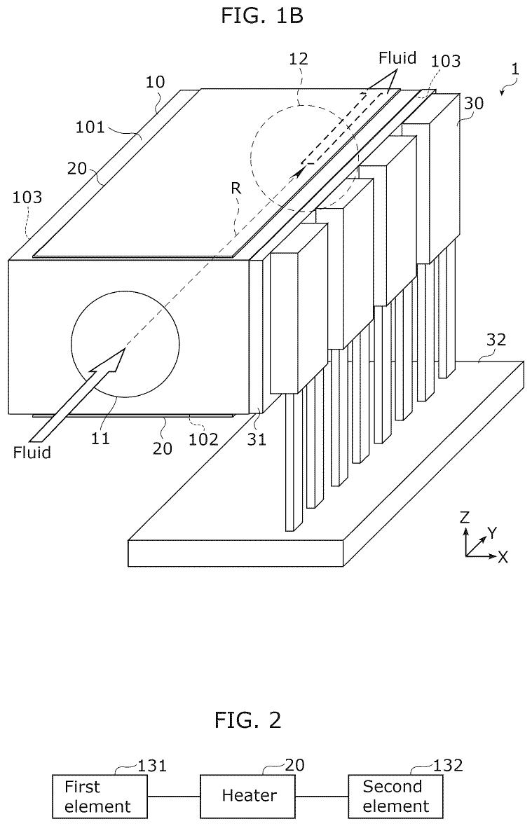

Referring to FIG. 1A, in the embodiment below, a direction in which a fluid flows toward a supply port is defined as a Y-axis positive direction, a direction extending toward the supply port relative to a discharge port is defined as an X-axis positive direction, and a direction that is perpendicular to the Y-axis positive direction and the X-axis positive direction and that extends toward a control element relative to a substrate is defined as a Z-axis positive direction. The directions in FIG. 1A may also be applied to FIG. 1B and subsequent drawings.

In the embodiment below, expressions such as a Y-axis direction and a linear shape are used. For example, a Y-axis direction and a linear shape refer not only to a perfect Y-axis direction and a perfect straight line, respectively, but also to a substantially Y-axis direction and a substantially straight line, respectively. In other words, for example, an error of about several percent is included. Furthermore, a Y-axis direction and a linear shape refer to a Y-axis direction and a linear shape within a range in which the advantages according to the present disclosure may be exhibited. The same applies to other expressions using “direction” and “shape”.

### Embodiment

First, the configuration of vehicle fluid heating device 1 will be described with reference to FIG. 1A to FIG. 4.

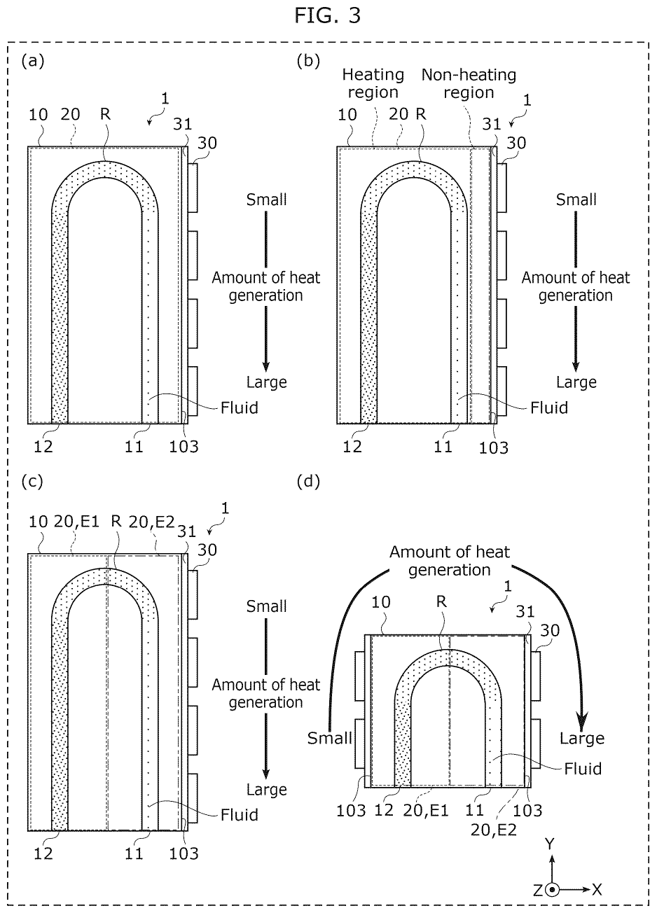

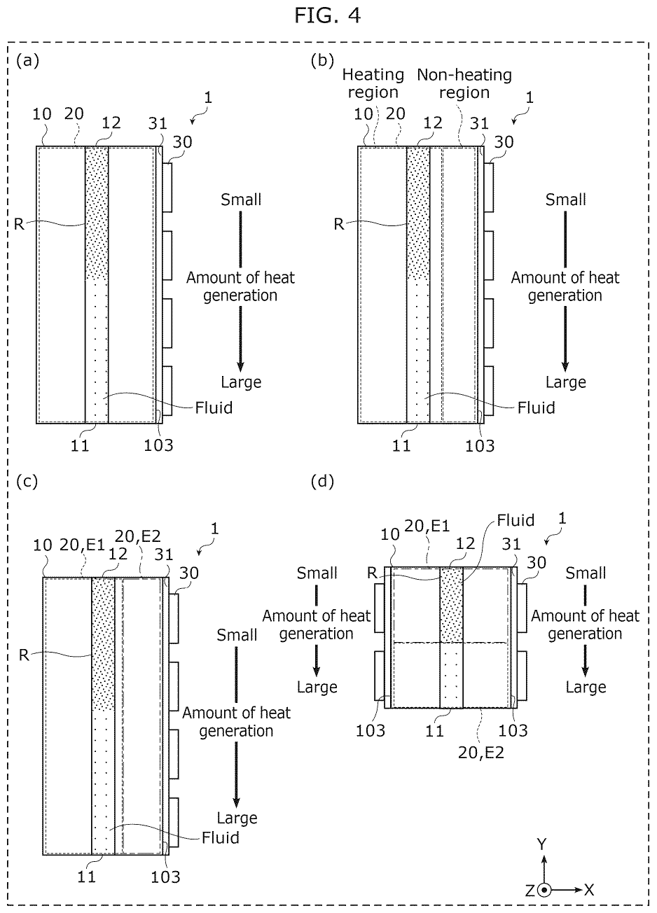

FIG. 1A is a perspective view illustrating vehicle fluid heating device 1 according to an embodiment. FIG. 1B is another perspective view illustrating vehicle fluid heating device 1 according to the embodiment. FIG. 2 is a block diagram illustrating vehicle fluid heating device 1 according to the embodiment. FIG. 3 is a plan view illustrating flow path R and heater 20 of vehicle fluid heating device 1. In (a) of FIG. 3, a fluid flowing through U-shaped or V-shaped flow path R is illustrated. In (b) of FIG. 3, a heating region indicated by a dashed line and a non-heating region indicated by a double-dot chain line are illustrated. In (c) of FIG. 3, heater 20 is disposed on tank 10 such that first area E1 of heater 20 covers flow path R at the side opposite from control elements 30 and second area E2 of heater 20 covers flow path R at the side near control elements 30. In (d) of FIG. 3, control elements 30 are disposed on opposite side surfaces 103 of tank 10. FIG. 4 is another plan view illustrating flow path R and heater 20 of vehicle fluid heating device 1. In (a) of FIG. 4, a fluid flowing through linear flow path R is illustrated. In (b) of FIG. 4, a heating region indicated by a dashed line and a non-heating region indicated by a double-dot chain line are illustrated. In (c) of FIG. 4, heater 20 is disposed on tank 10 such that first area E1 of heater 20 covers flow path R and second area E2 of heater 20 is disposed between flow path R and control elements 30. In (d) of FIG. 4, control elements 30 are disposed on opposite side surfaces 103 of tank 10.

In FIG. 3, the temperature of the fluid becomes higher as hatching indicated by dots becomes denser. In order to facilitate understanding, flow path R is indicated by a solid line and heater 20 is indicated by a dashed line in FIG. 3. The same applies to FIG. 4 and subsequent drawings.

As illustrated in FIG. 1A, vehicle fluid heating device 1 is applied to a vehicle air conditioning device, a vehicle battery, or the like installed in a vehicle, such as an electric vehicle (EV), a hybrid electric vehicle (HEV), or a plug-in hybrid electric vehicle (PHEV). When applied to, for example, a vehicle air conditioning device, vehicle fluid heating device 1 heats the fluid when the vehicle air conditioning device executes heating operation. Accordingly, the vehicle air conditioning device can deliver heated air into the vehicle cabin of the vehicle.

As illustrated in FIG. 1A and FIG. 2, vehicle fluid heating device 1 includes tank 10, heater 20, and control elements 30.

As illustrated in FIG. 1A, tank 10 is flat and long. In detail, tank 10 is a container that is flat in the Z-axis direction and long in the Y-axis direction. In other words, tank 10 is a container having a flat plate shape that is parallel to an XY plane. Tank 10 is composed of, for example, a metallic material such as aluminum.

Tank 10 internally includes flow path R that guides the fluid. In detail, tank 10 includes supply port 11 through which the fluid is to be supplied into tank 10 from the outside, and also includes discharge port 12 through which the fluid having traveled through flow path R in tank 10 is to be discharged outward.

Supply port 11 and discharge port 12 are disposed in an end surface at the Y-axis negative side of tank 10. In other words, supply port 11 and discharge port 12 are disposed at one end of tank 10. Supply port 11 and discharge port 12 are arranged in the X-axis direction, and supply port 11 is disposed at the X-axis positive side of discharge port 12. Due to such a configuration, in this embodiment, when flow path R is viewed in the Z-axis direction, flow path R is formed in a U-shaped or V-shaped turn, as illustrated in FIG. 1A and (a) of FIG. 3. Alternatively, in this embodiment, flow path R may have a linear shape, such as an I-shape, as illustrated in FIG. 1B and (a) of FIG. 4.

Each of supply port 11 and discharge port 12 is a connection port connectable to a hose (not illustrated). Supply port 11 is connected to a hose into which the fluid is to flow, and discharge port 12 is connected to a hose from which the fluid is to flow out. With each of supply port 11 and discharge port 12 being connected to a hose, the fluid can travel through flow path R in tank 10. The fluid is, for example, a liquid such as a coolant.

As illustrated in FIG. 1A and FIG. 3, heater 20 is disposed on each of one surface at the Z-axis positive side of tank 10 and the other surface at the Z-axis negative side of tank 10.

In detail, heater 20 is disposed on each of front surface 101 at the Z-axis positive side of tank 10 and rear surface 102 at the Z-axis negative side of tank 10. In other words, heaters 20 are disposed on front surface 101 of tank 10 and rear surface 102 of tank 10 to sandwich tank 10. Heaters 20 are laminated members having a shape corresponding to the external shape of tank 10.

Heaters 20 can heat tank 10 by generating heat. Accordingly, when traveling through tank 10, the fluid supplied from supply port 11 of tank 10 is heated by heaters 20, whereby the fluid that has been heated can be discharged from discharge port 12.

A thermal interface material may be interposed between each heater 20 and tank 10. In other words, a thermal interface material may be disposed on each of one surface at the Z-axis positive side of tank 10 and the other surface at the Z-axis negative side of tank 10. The thermal interface materials may be configured to be capable of transferring the heat generated by heaters 20 to tank 10. The thermal interface materials are each composed of, for example, a heat conductive material using silicon.

A substrate may be laminated on the other surface of each heater 20 opposite the surface thereof at the tank 10 side. The substrate may be composed of, for example, a heat resistant material, such as stainless steel. The thermal conductivity of the substrate may be lower than the thermal conductivity of tank 10. In this case, when heater 20 generates heat, the heat is transferred more readily toward tank 10 than toward the substrate.

Heaters 20 are laminated on opposite surfaces of tank 10 and are fixed to tank 10 by using screws or the like.

Heaters 20 are electrically connected to control elements 30 via substrate 32. Substrate 32 has a shape of a long plate extending in the Y-axis direction and is disposed alongside tank 10. Substrate 32 can control the operation of multiple control elements 30 to control heaters 20. By controlling the driving of heaters 20, substrate 32 can adjust the temperature of the fluid in tank 10, the heating period, and/or the like. In this embodiment, vehicle fluid heating device 1 may further include substrate 32 as a component.

Control elements 30 are disposed on side surface 103 of tank 10 having a rectangular-parallelepiped shape. In detail, control elements 30 are disposed on side surface 103 of tank 10 different from front surface 101 of tank 10 and rear surface 102 of tank 10 where heaters 20 are disposed. In the case illustrated in FIG. 1A and (a) of FIG. 3, since supply port 11 is disposed at the X-axis positive side of tank 10 relative to discharge port 12, multiple control elements 30 arranged in the Y-axis direction are disposed on side surface 103 at the X-axis positive side.

Multiple control elements 30 include first element 131 and second element 132.

As illustrated in FIG. 2, first element 131 is configured to control heaters 20. In first element 131, the electric power to be supplied to heaters 20 per unit time is kept constant by performing switching control. Accordingly, first element 131 tends to become higher in temperature than second element 132 where a switching loss occurs and where switching control is not performed.

Second element 132 is constantly in an ON mode when heaters 20 are driven. Therefore, second element 132 generates heat when in the ON mode. For example, second element 132 is configured to control heaters 20 when first element 131 fails. For example, when first element 131 is stuck in the ON mode, second element 132 can stop the supply of electric power to heaters 20. Accordingly, heaters 20 are controlled by single first element 131, and are controlled by single second element 132 when single first element 131 fails.

Since four control elements 30 are disposed in this embodiment, for example, first control element 30A, second control element 30B, third control element 30C, and fourth control element 30D as four control elements 30 may be arranged in the Y-axis positive direction, as illustrated in FIG. 1A and FIG. 2. In this case, first control element 30A may be configured to serve as first element 131 to control heater 20 on front surface 101 of tank 10, and second control element 30B may be configured to serve as second element 132 to control heater 20 on front surface 101 of tank 10. Moreover, third control element 30C may be configured to serve as first element 131 to control heater 20 on rear surface 102 of tank 10, and fourth control element 30D may be configured to serve as second element 132 to control heater 20 on rear surface 102 of tank 10. The number of control elements 30 may be three or less, or may be five or more.

A failure includes a case where switching between ON and OFF modes is not possible for heater 20 and a case where control element 30 is separated from side surface 103 of tank 10.

Vehicle fluid heating device 1 further includes planar contact layer 31. Contact layer 31 is disposed between control elements 30 and tank 10. In other words, control elements 30 are disposed in close contact with side surface 103 of tank 10 via contact layer 31. Contact layer 31 has insulation properties. Because tank 10 is composed of a metallic material, such as aluminum, contact layer 31 insulates control elements 30 to prevent them from conducting electricity to tank 10.

Multiple control elements 30 have different amounts of heat generation. Therefore, in this embodiment, control element 30 with a larger amount of heat generation among multiple control elements 30 is disposed closer to supply port 11. In other words, the liquid flowing through flow path R in tank 10 becomes lower in temperature with decreasing distance to supply port 11 and becomes higher in temperature with decreasing distance to discharge port 12. Accordingly, control element 30 with a larger amount of heat generation is disposed closer to supply port 11, so that control element 30 with a larger amount of heat generation can be readily cooled.

Although the above description relates to the case where heaters 20 heat front surface 101 of tank 10 and rear surface 102 of tank 10, the embodiment is not limited to this configuration. The following description with reference to (b) and (c) of FIG. 3 and (b) and (c) of FIG. 4 relates to a case where a part of front surface 101 of tank 10 and a part of rear surface 102 of tank 10 do not have to be heated and the heat generation density may be reduced.

For example, as illustrated in (b) of FIG. 3 and (b) of FIG. 4, each heater 20 may be disposed in a different area corresponding to flow path R and excluding an area corresponding to a region between control elements 30 and flow path R. In other words, tank 10 may include a heating region where heater 20 is disposed and a non-heating region where heater 20 is not disposed. The non-heating region may be located between the heating region and control elements 30.

Alternatively, as illustrated in (c) of FIG. 3 and (c) of FIG. 4, in each heater 20, the heat generation density in the area corresponding to the region between control elements 30 and flow path R may be lower than the heat generation density in the different area other than the aforementioned area. In detail, tank 10 may have a first heating region with a high heat generation density and a second heating region with a lower heat generation density than the first heating region. The first heating region may be located between the second heating region and control elements 30.

In this case, heater 20 may include first area E1 that heats flow path R at the side opposite from control elements 30, and may also include second area E2 that heats flow path R at the side near control elements 30. In (c) of FIG. 3, it can also be regarded that, with respect to flow path R, each heater 20 includes second area E2 that heats flow path R at the supply port 11 side and first area E1 that heats flow path R at the discharge port 12 side.

The first heating region of tank 10 may correspond to second area E2 of heater 20, and the second heating region of tank 10 may correspond to first area E1 of heater 20. In heater 20, first area E1 and second area E2 may be independently separated from each other, first area E1 and second area E2 may be integrated with each other, or first area E1 and second area E2 may be individually controlled by being divided from each other.

Control elements 30 may be capable of independently controlling first area E1 and second area E2. For example, control elements 30 can turn on heat generation in first area E1 and turn off heat generation in second area E2. In this case, second area E2 heats flow path R in accordance with heat generation of control elements 30. Furthermore, control elements 30 can set heat generation in first area E1 to “high” and set heat generation in second area E2 to “low”. When the temperature of the fluid is low, control elements 30 can also set heat generation in first area E1 and heat generation in second area E2 to “high”.

Accordingly, heating of control elements 30 by heaters 20 can be suppressed, and heat generated by control elements 30 can be dissipated to tank 10.

Although the above description relates to the case where multiple control elements 30 are disposed on one of side surfaces 103 of tank 10, the embodiment is not limited to this configuration. The following description with reference to (d) of FIG. 3 and (d) of FIG. 4 relates to a case where control elements 30 are disposed on opposite side surfaces 103 of tank 10.

For example, multiple control elements 30 may be disposed at tank 10 to sandwich flow path R. In detail, control elements 30 may be disposed on side surface 103 at the X-axis positive side of tank 10 and side surface 103 at the X-axis negative side of tank 10. In this case, control elements 30 with larger amounts of heat generation among multiple control elements 30 may be disposed on side surface 103 at the supply port 11 side (i.e., the X-axis positive side), and control elements 30 with smaller amounts of heat generation may be disposed on side surface 103 at the discharge port 12 side (i.e., the X-axis negative side).

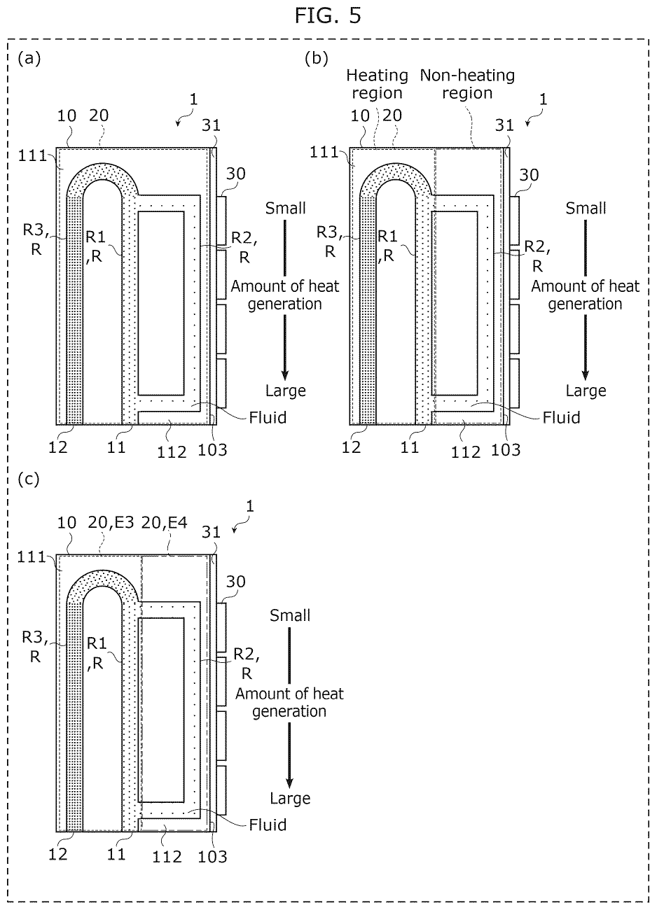

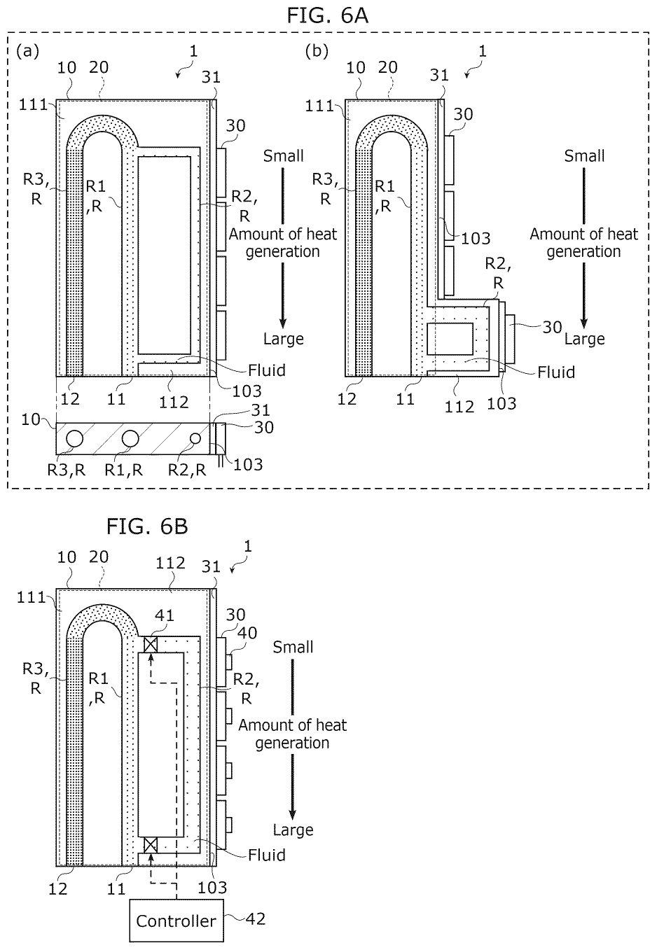

Although the above description relates to single flow path R as an example, the embodiment is not limited to this configuration. Flow path R will be described with reference to FIG. 5 and FIG. 6A.

FIG. 5 is a plan view illustrating first flow path R1, second flow path R2, third flow path R3, and heater 20 of vehicle fluid heating device 1. In (a) of FIG. 5, heater 20 is disposed on tank 10 such that heater 20 covers first flow path R1, second flow path R2, and third flow path R3. In (b) of FIG. 5, heater 20 is disposed on tank 10 such that heater 20 covers first flow path R1 and third flow path R3 but does not cover second flow path R2. In (c) of FIG. 5, heater 20 is disposed on tank 10 such that third area E3 of heater 20 covers first flow path R1 and third flow path R3 and that fourth area E4 of heater 20 covers second flow path R2. FIG. 6A is another plan view illustrating first flow path R1, second flow path R2, third flow path R3, and heater 20 of vehicle fluid heating device 1. In (a) of FIG. 6A, second flow path R2 has a smaller cross-sectional area than those of first flow path R1 and third flow path R3. In (b) of FIG. 6A, second flow path R2 is provided for disposing control element 30 high in temperature.

Although flow path R is U-shaped or V-shaped in FIG. 5, flow path R may be I-shaped. The same applies to FIG. 6A and subsequent drawings.

For example, as illustrated in (a) of FIG. 5, flow path R may include first flow path R1 and second flow path R2 into which the fluid is to flow from supply port 11 of tank 10, and may also include third flow path R3 through which the fluid from at least one of first flow path R1 or second flow path R2 is to flow.

Second flow path R2 may be a bypass flow path from first flow path R1. In this case, an upstream end of second flow path R2 may be connected to an upstream end of first flow path R1, and a downstream end of second flow path R2 may be connected to at least one of a downstream end of first flow path R1 or an upstream end of third flow path R3.

Control elements 30 may be disposed on side surface 103 of tank 10 to be in contact with second flow path R2. Since second flow path R2 is a bypass flow path from first flow path R1 in FIG. 5, control elements 30 may be disposed on side surface 103 of tank 10 to be in contact with second flow path R2.

Second flow path R2 bypassing first flow path R1 is lower in temperature than first flow path R1 or third flow path R3. Thus, control elements 30 can be readily cooled.

For example, as illustrated in (b) of FIG. 5, heater 20 may be disposed in a different area corresponding to first flow path R1 and third flow path R3 and excluding an area corresponding to a region between control elements 30 and first flow path R1, that is, an area corresponding to second flow path R2. In other words, tank 10 may include a heating region where heater 20 is disposed and a non-heating region where heater 20 is not disposed. The non-heating region may be located between the heating region and control elements 30.

Alternatively, as illustrated in (c) of FIG. 5, in heater 20, the heat generation density in the area corresponding to the region between control elements 30 and first flow path R1 may be lower than the heat generation density in the different area other than the aforementioned area. In detail, tank 10 may have a first heating region with a high heat generation density and a second heating region with a lower heat generation density than the first heating region. The second heating region may be located between the first heating region and control elements 30.

In this case, heater 20 may include third area E3 corresponding to first flow path R1 and third flow path R3, and may also include fourth area E4 corresponding to second flow path R2. Fourth area E4 may be located between third area E3 and control element 30. In other words, the first heating region of tank 10 may correspond to third area E3 of heater 20, and the second heating region of tank 10 may correspond to fourth area E4 of heater 20.

Control elements 30 may be capable of individually controlling third area E3 and fourth area E4. For example, control elements 30 can turn off heat generation in fourth area E4 and turn on heat generation in third area E3. Furthermore, control elements 30 can set heat generation in fourth area E4 to “low” and set heat generation in third area E3 to “high”. When the temperature of the fluid is low, control elements 30 can also set heat generation in third area E3 and heat generation in fourth area E4 to “high”.

In (a) of FIG. 6A, the cross-sectional areas of first flow path R1, second flow path R2, and third flow path R3 are illustrated.

Although first flow path R1, second flow path R2, and third flow path R3 may have the same cross-sectional area, the cross-sectional area of second flow path R2 may be smaller than the cross-sectional area of first flow path R1 and may be smaller than the cross-sectional area of third flow path R3, as illustrated in (a) of FIG. 6A. The cross-sectional area of first flow path R1 may be similar to the cross-sectional area of third flow path R3.

In (b) of FIG. 6A, the arrangement of control elements 30 is illustrated.

Although multiple control elements 30 are disposed on side surface 103 of tank 10 to be in contact with second flow path R2, control element 30 with the largest amount of heat generation among multiple control elements 30 may be disposed alone on side surface 103 of tank 10 to be in contact with second flow path R2, as illustrated in (b) of FIG. 6A. Hence, the length of second flow path R2 can be minimized, whereby an increase in size of vehicle fluid heating device 1 can be suppressed.

Although the above description relates to the case where vehicle fluid heating device 1 includes tank 10, heaters 20, and control elements 30, the embodiment is not limited to this configuration. Vehicle fluid heating device 1 will be described with reference to FIG. 6B.

FIG. 6B is a plan view illustrating first flow path R1, second flow path R2, third flow path R3, and heater 20 of vehicle fluid heating device 1 including controller 42 and valve 41.

As illustrated in FIG. 6B, vehicle fluid heating device 1 may further include valve 41, temperature detector 40, and controller 42.

Valve 41 may be disposed in tank 10 and be configured to control the inflow amount of the fluid flowing into second flow path R2. Valve 41 may be disposed at each of the upstream side and the downstream side of second flow path R2, or may be disposed only at either of the upstream side and the downstream side.

Temperature detector 40 may be configured to detect the temperature of each control element 30.

In this case, temperature detector 40 may be attached to each control element 30. Since vehicle fluid heating device 1 includes multiple control elements 30, multiple temperature detectors 40 may be disposed to correspond in a one-to-one fashion with multiple control elements 30.

Temperature detector 40 may output a detection result indicating the detected temperature of each control element 30 to controller 42.

Controller 42 may be configured to control the opening and closing of valve 41. Controller 42 may close valve 41 if the temperature detected by temperature detector 40 is less than a first predetermined value, and may open valve 41 if the temperature detected by temperature detector 40 is greater than or equal to the first predetermined value. For example, controller 42 is implemented by a processor, such as a central processing unit (CPU), executing a computer program.

For example, since it is conceivable that vehicle fluid heating device 1 is low in temperature (e.g., 20° C. or lower) when vehicle fluid heating device 1 is to be activated, controller 42 may close valve 41. When a predetermined period elapses from activation, control elements 30 increase in temperature, so that controller 42 may open valve 41 and cool control elements 30.

Although FIG. 6B illustrates an example where temperature detector 40 is attached to each control element 30, temperature detector 40 may be disposed at tank 10. In this case, controller 42 may close valve 41 if the temperature detected by temperature detector 40 is less than the first predetermined value, and may open valve 41 if the temperature detected by temperature detector 40 is greater than or equal to the first predetermined value.

For example, since it is conceivable that vehicle fluid heating device 1 is low in temperature (e.g., 20° C. or lower) when vehicle fluid heating device 1 is to be activated, heat can be dissipated from control elements 30 to tank 10 itself if the temperature of tank 10 is low (i.e., less than the first predetermined value). Thus, it is not necessary to cause the fluid to flow to second flow path R2. Hence, control may be performed for closing valve 41 to prevent the fluid from flowing into second flow path R2.

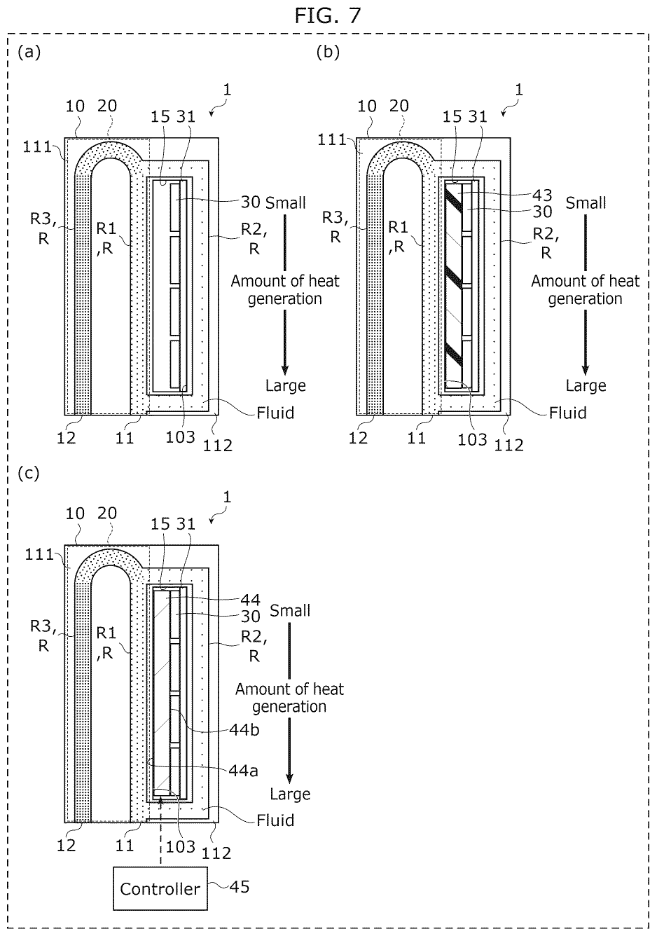

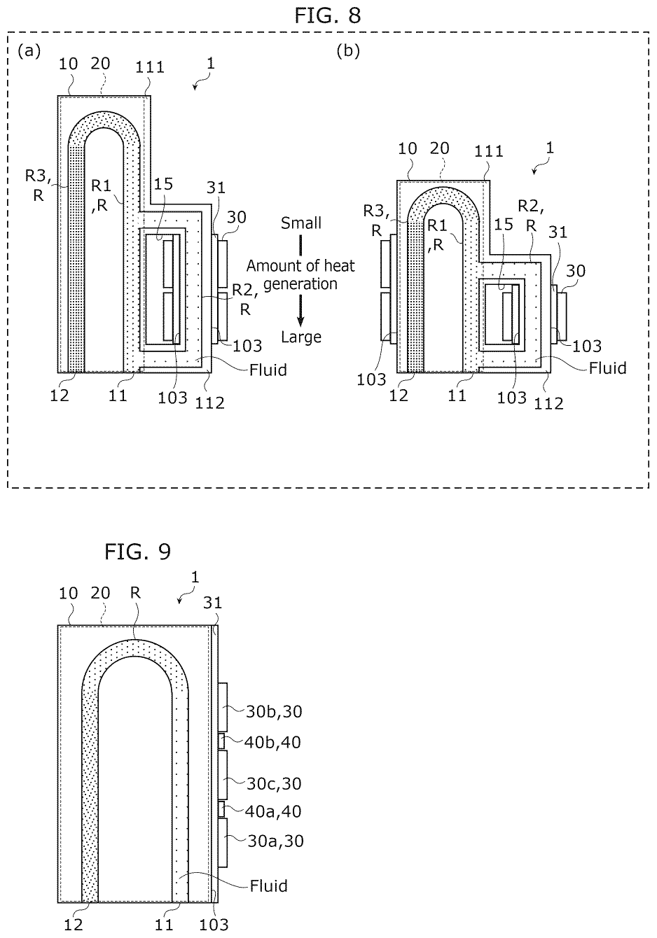

Although the above description relates to the case or the like where tank 10 includes flow path R, the embodiment is not limited to this configuration. Tank 10 will be described with reference to FIG. 7 and FIG. 8.

FIG. 7 is a plan view illustrating first flow path R1, second flow path R2, third flow path R3, and heater 20 of vehicle fluid heating device 1 having cavity 15. In (a) of FIG. 7, multiple control elements 30 are disposed in cavity 15. In (b) of FIG. 7, multiple control elements 30 and fixation section 43 are disposed in cavity 15. In (c) of FIG. 7, multiple control elements 30 and thermoelectric element 44 are disposed in cavity 15. FIG. 8 is another plan view illustrating first flow path R1, second flow path R2, third flow path R3, and heater 20 of vehicle fluid heating device 1 having cavity 15. In (a) of FIG. 8, multiple control elements 30 are disposed to sandwich second body 112 of second flow path R2. In (b) of FIG. 8, two or more control elements 30 are disposed to sandwich second body 112 of second flow path R2, and two or more control elements 30 are also disposed at first body 111.

As illustrated in (a) of FIG. 7, tank 10 may have cavity 15 between first flow path R1 and second flow path R2. In other words, tank 10 may include first body 111 provided with first flow path R1 and third flow path R3 and second body 112 integrally connected to first body 111 and provided with second flow path R2. Cavity 15 may be provided between first body 111 and second body 112. In this embodiment, cavity 15 may be a through-hole provided in tank 10.

At least one of control elements 30 may be disposed in cavity 15 to be in contact with second flow path R2. In this case, the at least one control element 30 may be disposed on an inner wall surface of cavity 15 (i.e., side surface 103 of tank 10) via contact layer 31.

As illustrated in (b) of FIG. 7, vehicle fluid heating device 1 may further include fixation section 43.

Fixation section 43 may be disposed in cavity 15 to fill in a space between side surface 103 of tank 10 provided with first flow path R1 and control elements 30. Fixation section 43 is composed of, for example, a resin material. Control elements 30 are pressed against the inner wall surface of cavity 15 by fixation section 43, so that control elements 30 are less likely to become separated from the inner wall surface of cavity 15.

As illustrated in (c) of FIG. 7, in place of fixation section 43, vehicle fluid heating device 1 may further include thermoelectric element 44 and controller 45.

Thermoelectric element 44 may be disposed in cavity 15 to fill in the space between side surface 103 of tank 10 forming first flow path R1 and control elements 30. Thermoelectric element 44 is, for example, a Peltier element. In this case, thermoelectric element 44 may have cooling surface 44b that is in close contact with control elements 30, and heat generating surface 44a that is in close contact with side surface 103 of tank 10. Control elements 30 are pressed against the inner wall surface of cavity 15 by thermoelectric element 44, so that control elements 30 are less likely to become separated from the inner wall surface of cavity 15. In addition, thermoelectric element 44 can cool control elements 30 and can also heat first body 111.

Controller 45 may be configured to control thermoelectric element 44. Controller 45 may drive thermoelectric element 44 to cause thermoelectric element 44 to cool control elements 30 and also heat first body 111, or may stop thermoelectric element 44. With vehicle fluid heating device 1 being equipped with temperature detector 40 mentioned above, controller 45 may control the driving of thermoelectric element 44 in accordance with the temperature detected by temperature detector 40, similarly to the above description with reference to FIG. 6B.

Controller 45 is implemented by a processor, such as a central processing unit (CPU), executing a computer program.

As illustrated (a) of FIG. 8, one or more control elements 30 among multiple control elements 30 may be disposed on the inner wall surface (i.e., side surface 103) of cavity 15, and the remaining one or more control elements 30 may be disposed outward of cavity 15 and on side surface 103 of second body 112 to be in contact with second flow path R2. Accordingly, multiple control elements 30 sandwich second body 112 of second flow path R2, so that an increase in length of second body 112 can be suppressed, whereby an increase in length of first body 111 can also be suppressed. Consequently, an increase in size of tank 10 can be expected to be suppressed.

As illustrated in (b) of FIG. 8, one or more control elements 30 among multiple control elements 30 may be disposed to sandwich second body 112 of second flow path R2, and the remaining one or more control elements 30 may be disposed on side surface 103 of first body 111 opposite from second body 112. In this case, the one or more control elements 30 may sandwich second body 112 of second flow path R2, and the remaining one or more control elements 30 may be disposed on side surface 103 located near third flow path R3 of first body 111 at the third flow path R3 side. Accordingly, an increase in length of second body 112 can be further suppressed, whereby an increase in length of first body 111 can be further suppressed. Consequently, an increase in size of tank 10 can be expected to be suppressed.

In this case, control element 30 with a larger amount of heat generation may be disposed on side surface 103 of second body 112, and control element 30 with a smaller amount of heat generation may be disposed on side surface 103 of first body 111.

Although the above description relates to the case where vehicle fluid heating device 1 includes tank 10, heaters 20, and control elements 30, the embodiment is not limited to this configuration. Vehicle fluid heating device 1 will be described with reference to FIG. 9.

FIG. 9 is a plan view illustrating vehicle fluid heating device 1 including temperature detector 40 disposed at tank 10. In order to facilitate understanding, three control elements 30 are illustrated as an example in FIG. 9.

As illustrated in FIG. 9, vehicle fluid heating device 1 may further include temperature detector 40.

Temperature detector 40 may be configured to detect the temperature of tank 10.

In this case, temperature detector 40 may be attached to side surface 103 of tank 10 to be adjacent to control elements 30.

Control elements 30 may control heaters 20 to stop heating tank 10 if the temperature detected by temperature detector 40 is greater than or equal to a second predetermined value. Control elements 30 may control heaters 20 to continue heating the fluid if the temperature detected by temperature detector 40 is less than the second predetermined value.

Because multiple control elements 30 are disposed on tank 10, multiple control elements 30 may include first control element 30a with the largest amount of heat generation, second control element 30b with the next largest amount of heat generation after first control element 30a, and third control element 30c with a smaller amount of heat generation than first control element 30a or second control element 30b.

Control elements 30 may control heaters 20 to stop heating tank 10 if the temperature detected by at least one of first temperature detector 40a or second temperature detector 40b is greater than or equal to the second predetermined value.

In this case, vehicle fluid heating device 1 may include multiple temperature detectors 40.

Multiple temperature detectors 40 may include first temperature detector 40a and second temperature detector 40b that detect the temperatures of multiple control elements 30.

First temperature detector 40a may be disposed on side surface 103 to be adjacent to first control element 30a and third control element 30c.

Second temperature detector 40b may be disposed on side surface 103 to be adjacent to second control element 30b and third control element 30c.

In this case, when first temperature detector 40a detects a temperature greater than or equal to the second predetermined value, it can be estimated that first control element 30a has failed due to high temperature since first control element 30a with a large amount of heat generation and third control element 30c with a smaller amount of heat generation than first control element 30a are arranged alongside each other.

When second temperature detector 40b detects a temperature greater than or equal to the second predetermined value, it can be estimated that second control element 30b has failed due to high temperature since second control element 30b with a large amount of heat generation and third control element 30c with a smaller amount of heat generation than second control element 30b are arranged alongside each other.

### Advantageous Effects

Next, the advantageous effects of vehicle fluid heating device 1 according to this embodiment will be described.

In the heating element casing in PTL 1, the heating element and the like can be utilized when the liquid is to be heated. In this case, it is conceivable that a semiconductor element for controlling electric current flowing toward the heating element is necessary. When the semiconductor element is to control the heating element, the semiconductor element also generates heat, so that the power consumption of the semiconductor element increases. In view of this, in order to suppress a temperature rise in the semiconductor element due to the heat generation, it is conceivable to provide the semiconductor element with a heat dissipation mechanism. However, providing a heat dissipation mechanism leads to an increase in size of the heating element casing. This is problematic in terms of an increase in manufacturing cost.

In view of this, as mentioned above, vehicle fluid heating device 1 of technique 1 according to this embodiment includes tank 10 internally including flow path R that guides a fluid, heater 20 that is disposed to sandwich tank 10 and heats the fluid by heating tank 10, and at least one control element 30 that controls heater 20. Tank 10 includes front surface 101 and rear surface 102 that are where heater 20 is disposed, and side surface 103 different from front surface 101 and rear surface 102. Control element 30 is disposed on side surface 103 of tank 10.

Accordingly, even when control element 30 generates heat, the heat can be released to tank 10. Thus, the heat can be dissipated from control element 30 to tank 10 without providing a heat dissipation mechanism for cooling control element 30.

The heat of control element 30 can also be used for increasing the temperature of the fluid. Thus, an increase in size of heater 20 can be suppressed.

Consequently, with vehicle fluid heating device 1, an increase in size and an increase in manufacturing cost can be suppressed.

In particular, since the heat can be dissipated from control element 30 to tank 10, a temperature rise of control element 30 can be suppressed. Thus, an increase in power consumption of control element 30 can be suppressed.

Since a temperature rise of control element 30 can be suppressed with a simple configuration, a complex structure of vehicle fluid heating device 1 can be suppressed.

Vehicle fluid heating device 1 of technique 2 according to this embodiment is vehicle fluid heating device 1 according to technique 1. In this case, vehicle fluid heating device 1 further includes contact layer 31 that is planar and disposed on side surface 103 of tank 10. Contact layer 31 is disposed between tank 10 and control element 30.

Accordingly, since control element 30 is in contact with tank 10 via contact layer 31, heat can be readily dissipated from control element 30 to tank 10.

Moreover, since control element 30 is in contact with contact layer 31, control element 30 can be retained by side surface 103 of tank 10.

When tank 10 is composed of metal, if contact layer 31 has insulation properties, electrical conduction between control element 30 and tank 10 can be suppressed.

Vehicle fluid heating device 1 of technique 3 according to this embodiment is vehicle fluid heating device 1 according to technique 2. In this case, control element 30 is disposed in close contact with side surface 103 via contact layer 31.

Accordingly, the contact area between control element 30 and tank 10 via contact layer 31 can be increased, so that heat can be readily dissipated from control element 30 to tank 10.

Vehicle fluid heating device 1 of technique 4 according to this embodiment is vehicle fluid heating device 1 according to any one of techniques 1 to 3. In this case, flow path R includes supply port 11 through which the fluid is to be supplied into tank 10 from the outside, and discharge port 12 through which the fluid that has traveled through flow path R in tank 10 is to be discharged outward. Multiple control elements 30 are disposed at tank 10. Of multiple control elements 30, control element 30 with a larger amount of heat generation is disposed closer to supply port 11.

Accordingly, the temperature of the fluid flowing into supply port 11 is lower than that at discharge port 12, so that a portion of tank 10 close to supply port 11 is lower in temperature than a portion close to discharge port 12. Thus, by disposing control element 30 with the larger amount of heat generation closer to supply port 11 on side surface 103 of tank 10, heat can be dissipated from control element 30 with the larger amount of heat generation to tank 10. In other words, the cooling performance against control element 30 with the larger amount of heat generation can be expected to be improved.

Vehicle fluid heating device 1 of technique 5 according to this embodiment is vehicle fluid heating device 1 according to any one of techniques 1 to 4. In this case, flow path R includes supply port 11 through which the fluid is to be supplied into tank 10 from the outside, and discharge port 12 through which the fluid that has traveled through flow path R in tank 10 is to be discharged outward. Multiple control elements 30 are disposed at tank 10. Multiple control elements 30 include first element 131 that controls heater 20 and second element 132 that controls heater 20 when first element 131 fails. First element 131 is disposed closer to supply port 11 than second element 132 is.

Accordingly, first element 131 with a larger amount of heat generation than second element 132 is disposed on side surface 103 of tank 10 so as to be closer to supply port 11, whereby heat can be dissipated from first element 131 with the larger amount of heat generation to tank 10. In other words, the cooling performance against first element 131 with the larger amount of heat generation can be expected to be improved.

Vehicle fluid heating device 1 of technique 6 according to this embodiment is vehicle fluid heating device 1 according to any one of techniques 1 to 5. In this case, heater 20 is disposed in a different area corresponding to flow path R and excluding an area corresponding to a region between control element 30 and flow path R. Alternatively, heater 20 has a lower heat generation density in the area than a heat generation density in the different area.

Accordingly, heater 20 can be disposed at a position located away from control element 30. Thus, excessive heating of control element 30 can be suppressed. In other words, inhibition of heat dissipation from control element 30 to tank 10 by heater 20 can be suppressed.

Furthermore, since heater 20 has a lower heat generation density in the area corresponding to the region between control element 30 and flow path R than the heat generation density in the different area, excessive heating of control element 30 can be suppressed. In other words, inhibition of heat dissipation from control element 30 to tank 10 by heater 20 can be suppressed. Moreover, since the fluid that has traveled through second flow path R2 can be heated by control element 30, an excessive temperature decrease in the fluid returning to first flow path R1 or third flow path R3 can be suppressed. Accordingly, the fluid can be heated to an extent at which control element 30 is not affected.

Vehicle fluid heating device 1 of technique 7 according to this embodiment is vehicle fluid heating device 1 according to any one of techniques 1 to 5. In this case, tank 10 includes a heating region where heater 20 is disposed and a non-heating region where heater 20 is not disposed. The non-heating region is located between the heating region and control element 30.

Accordingly, since tank 10 is not heated in the non-heating region, excessive heating of control element 30 can be suppressed. In other words, inhibition of heat dissipation from control element 30 to tank 10 by heater 20 can be suppressed.

Vehicle fluid heating device 1 of technique 8 according to this embodiment is vehicle fluid heating device 1 according to any one of techniques 1 to 7. In this case, heater 20 includes first area E1 that heats flow path R located opposite from the control element side and second area E2 that heats flow path R located at the control element side. Flow path R located opposite from the control element side and flow path R located at the control element side are included in flow path R. Control element 30 individually controls first area E1 and second area E2.

Accordingly, heater 20 can be controlled for each area. For example, control element 30 can control heater 20 in second area E2 to prevent the temperature of second area E2 from becoming too high. Thus, excessive heating of control element 30 can be suppressed.

Vehicle fluid heating device 1 of technique 9 according to this embodiment is vehicle fluid heating device 1 according to any one of techniques 1 to 8. In this case, multiple control elements 30 are disposed at tank 10. Multiple control elements 30 are disposed to sandwich flow path R.

Accordingly, control elements 30 can be disposed at opposite sides of tank 10. Thus, tank 10 does not have to be increased in size for dissipating heat from multiple control elements 30 to tank 10. In other words, flow path R can be shortened, and tank 10 can be reduced in size.

Vehicle fluid heating device 1 of technique 10 according to this embodiment is vehicle fluid heating device 1 according to any one of techniques 1 to 9. In this case, flow path R includes first flow path R1 and second flow path R2 into which the fluid is to flow from supply port 11 of tank 10, and third flow path R3 through which the fluid is to flow from at least one of first flow path R1 or second flow path R2. Second flow path R2 is flow path R that bypasses first flow path R1. Control element 30 is disposed on side surface 103 to be in contact with second flow path R2.

Accordingly, second flow path R2 can be disposed at a position located away from first flow path R1, so that the temperature of the fluid flowing through second flow path R2 is lower than the temperature of the fluid flowing through first flow path R1. Thus, a portion of tank 10 forming second flow path R2 is lower in temperature than a portion of tank 10 forming first flow path R1. Consequently, heat can be dissipated from control element 30 to tank 10. In other words, control element 30 can be cooled efficiently.

Vehicle fluid heating device 1 of technique 11 according to this embodiment is vehicle fluid heating device 1 according to technique 10. In this case, heater 20 includes third area E3 corresponding to first flow path R1 and third flow path R3, and fourth area E4 corresponding to second flow path R2. Heater 20 has a lower heat generation density in fourth area E4 than a heat generation density in third area E3.

Accordingly, the heat generation density in fourth area E4 is lower than the heat generation density in third area E3, so that excessive heating of control element 30 can be suppressed. In other words, inhibition of heat dissipation from control element 30 to tank 10 by heater 20 can be suppressed.

Vehicle fluid heating device 1 of technique 12 according to this embodiment is vehicle fluid heating device 1 according to technique 10. In this case, heater 20 includes third area E3 corresponding to first flow path R1 and third flow path R3, and fourth area E4 corresponding to second flow path R2. Control element 30 individually controls third area E3 and fourth area E4.

Accordingly, heater 20 can be controlled for each area. For example, control element 30 can control heater 20 in fourth area E4 to prevent the temperature of fourth area E4 from becoming too high. Thus, excessive heating of control element 30 can be suppressed.

Vehicle fluid heating device 1 of technique 13 according to this embodiment is vehicle fluid heating device 1 according to any one of techniques 10 to 12. In this case, a cross-sectional area of second flow path R2 is smaller than a cross-sectional area of first flow path R1.

Accordingly, an increase in pressure loss of the fluid flowing through flow path R in tank 10 can be suppressed, and an increase in size of tank 10 can be suppressed.

Vehicle fluid heating device 1 of technique 14 according to this embodiment is vehicle fluid heating device 1 according to any one of techniques 10 to 12. In this case, multiple control elements 30 are disposed at tank 10. Of multiple control elements 30, control element 30 with a largest amount of heat generation is disposed alone on side surface 103 to be in contact with second flow path R2.

Accordingly, since an increase in length of second flow path R2 can be suppressed, an increase in pressure loss of the fluid flowing through flow path R in tank 10 can be suppressed, and an increase in size of tank 10 can also be suppressed.

Furthermore, heat from control element 30 with the largest amount of heat generation can be further dissipated to tank 10. In other words, the cooling performance against control element 30 with the largest amount of heat generation can be expected to be improved.

Vehicle fluid heating device 1 of technique 15 according to this embodiment is vehicle fluid heating device 1 according to any one of techniques 10 to 14. In this case, vehicle fluid heating device 1 further includes temperature detector 40 that detects a temperature of control element 30, valve 41 that is disposed in tank 10 and is used for controlling an inflow amount of the fluid flowing into second flow path R2, and controller 42 that controls opening and closing of valve 41. Controller 42 closes valve 41 when the temperature detected by temperature detector 40 is less than a first predetermined value, and opens valve 41 when the temperature detected by temperature detector 40 is greater than or equal to the first predetermined value.

Accordingly, heat does not have to be dissipated from control element 30 if the temperature of control element 30 is low (i.e., less than the first predetermined value), so that control may be performed for closing valve 41 to prevent the fluid from flowing into second flow path R2. Consequently, a pressure loss of the fluid flowing into flow path R in tank 10 can be suppressed.

If the temperature of control element 30 is high (i.e., greater than or equal to the first predetermined value), control can be performed for opening valve 41 to cause the fluid to flow into second flow path R2. Consequently, heat can be further dissipated from control element 30 to tank 10. In other words, control element 30 can be cooled efficiently.

Vehicle fluid heating device 1 of technique 16 according to this embodiment is vehicle fluid heating device 1 according to any one of techniques 10 to 14. In this case, vehicle fluid heating device 1 further includes temperature detector 40 that detects a temperature of tank 10, valve 41 that is disposed in tank 10 and is used for controlling an inflow amount of the fluid flowing into second flow path R2, and controller 42 that controls opening and closing of valve 41. Controller 42 closes valve 41 when the temperature detected by temperature detector 40 is less than a first predetermined value, and opens valve 41 when the temperature detected by temperature detector 40 is greater than or equal to the first predetermined value.

Accordingly, since heat can be dissipated from control element 30 to tank 10 itself if the temperature of tank 10 is low (i.e., less than the first predetermined value), the fluid does not have to flow into second flow path R2. Hence, control may be performed for closing valve 41 to prevent the fluid from flowing into second flow path R2, so that a pressure loss of the fluid flowing into flow path R in tank 10 can be suppressed.

If the temperature of tank 10 is high (i.e., greater than or equal to the first predetermined value), control can be performed for opening valve 41 to cause the fluid to flow into second flow path R2. Consequently, heat can be further dissipated from control element 30 to tank 10 and the fluid. In other words, control element 30 can be cooled efficiently.

Vehicle fluid heating device 1 of technique 17 according to this embodiment is vehicle fluid heating device 1 according to any one of techniques 10 to 16. In this case, tank 10 has cavity 15 between first flow path R1 and second flow path R2, and at least one control element 30 is disposed in cavity 15 to be in contact with second flow path R2.

Accordingly, a space can be formed between first flow path R1 and second flow path R2, so that heat transfer from tank 10 (first body 111) forming first flow path R1 to tank 10 (second body 112) forming second flow path R2 can be suppressed. Consequently, heater 20 can efficiently heat tank 10.

Vehicle fluid heating device 1 of technique 18 according to this embodiment is vehicle fluid heating device 1 according to technique 17. In this case, vehicle fluid heating device 1 further includes fixation section 43 disposed in cavity 15 to fill in a space between side surface 103 of tank 10 forming first flow path R1 and control element 30.

Accordingly, control element 30 can be fixed more securely to side surface 103 of tank 10 by fixation section 43.

Vehicle fluid heating device 1 of technique 19 according to this embodiment is vehicle fluid heating device 1 according to technique 17. In this case, vehicle fluid heating device 1 further includes thermoelectric element 44 disposed in cavity 15 to fill in a space between side surface 103 of tank 10 forming first flow path R1 and control element 30, and controller 45 that controls thermoelectric element 44.

Accordingly, by bringing cooling surface 44b of thermoelectric element 44 into contact with control element 30 and bringing heat generating surface 44a of thermoelectric element 44 into contact with side surface 103 of tank 10, control element 30 can be cooled, and tank 10 (first body 111) forming first flow path R1 can be heated.

Vehicle fluid heating device 1 of technique 20 according to this embodiment is vehicle fluid heating device 1 according to any one of techniques 1 to 19. In this case, vehicle fluid heating device 1 further includes temperature detector 40 that detects a temperature of control element 30. Temperature detector 40 is attached to control element 30.

Accordingly, temperature detector 40 can accurately detect the temperature of control element 30.

Vehicle fluid heating device 1 of technique 21 according to this embodiment is vehicle fluid heating device 1 according to any one of techniques 1 to 19. In this case, vehicle fluid heating device 1 further includes temperature detector 40 that detects a temperature of control element 30. Temperature detector 40 is attached to side surface 103 to be adjacent to control element 30. Control element 30 controls heater 20 to stop heating tank 10 when the temperature detected by temperature detector 40 is greater than or equal to a second predetermined value.

Accordingly, by stopping the heating of tank 10, excessive heating of control element 30 can be suppressed. In other words, inhibition of heat dissipation from control element 30 to tank 10 by heater 20 can be suppressed.

Vehicle fluid heating device 1 of technique 22 according to this embodiment is vehicle fluid heating device 1 according to any one of techniques 1 to 3. In this case, multiple control elements 30 are disposed at tank 10. Vehicle fluid heating device 1 further includes first temperature detector 40a and second temperature detector 40b that detect temperatures of multiple control elements 30. Multiple control elements 30 include first control element 30a with a largest amount of heat generation, second control element 30b with a next largest amount of heat generation after first control element 30a, and third control element 30c with a smaller amount of heat generation than first control element 30a or second control element 30b. First temperature detector 40a is disposed on side surface 103 to be adjacent to first control element 30a and third control element 30c. Second temperature detector 40b is disposed on side surface 103 to be adjacent to second control element 30b and third control element 30c. Control element 30 controls heater 20 to stop heating tank 10 when the temperature detected by at least one of first temperature detector 40a or second temperature detector 40b is greater than or equal to a second predetermined value.

Accordingly, third control element 30c stops heating of tank 10 by turning off electrical conduction to first control element 30a or second control element 30b estimated to have undergone a failure due to high temperature, whereby excessive heating of control elements 30 can be suppressed.

Moreover, since the temperatures of control elements 30 can be detected with a minimum number of temperature detectors 40, the number of temperature detectors 40 installed in vehicle fluid heating device 1 can be optimized. Consequently, an increase in manufacturing cost of vehicle fluid heating device 1 can be suppressed.

### Other Variations

Although the vehicle fluid heating device according to the present disclosure has been described above based on the above embodiment, the present disclosure is not limited to the above embodiment. An embodiment obtained by applying various variations conceivable by a skilled person to the above embodiment may be included in the scope of the present disclosure without departing from the spirit of the present disclosure.

For example, the heating region and the non-heating region are rectangular in the vehicle fluid heating device according to the present disclosure, but are not limited to this shape. For example, in (b) of FIG. 3, the heating region may have a triangular or trapezoidal shape that increases in width with increasing distance from discharge port 12, and the non-heating region may have a triangular or trapezoidal shape that decreases in width with increasing distance from supply port 11. In (b) of FIG. 4, the heating region may have a triangular or trapezoidal shape that decreases in width with increasing distance from discharge port 12, and the non-heating region may have a triangular or trapezoidal shape that decreases in width with increasing distance from supply port 11. Accordingly, heating near supply port 11 is suppressed, so that heating of control elements 30 can be expected to be suppressed. The same applies to the heating region and the non-heating region in FIG. 5 and subsequent drawings.

From this standpoint, in the relationship between the first area and the second area, the first area may be interpreted as the heating region, and the second area may be interpreted as the non-heating region. Therefore, the first area and the second area are not limited to having a rectangular shape, and may alternatively have a triangular or trapezoidal shape.

From this standpoint, in the relationship between the third area and the fourth area, the third area may be interpreted as the heating region, and the fourth area may be interpreted as the non-heating region. Therefore, the third area and the fourth area are not limited to having a rectangular shape, and may alternatively have a triangular or trapezoidal shape.

An embodiment obtained by applying various variations conceivable by a skilled person to the above embodiment and an embodiment obtained by freely combining components and functions in the embodiment without departing from the scope of the present disclosure are also included in the present disclosure.

While the embodiment has been described herein above, it is to be appreciated that various changes in form and detail may be made without departing from the spirit and scope of the present disclosure as presently or hereafter claimed.

### Further Information About Technical Background to This Application

The disclosure of the following patent application including specification, drawings, and claims are incorporated herein by reference in its entirety: Japanese Patent Application No. 2025-021382 filed on Feb. 13, 2025.

### Industrial Applicability

The present disclosure can be used in a vehicle fluid heating device, such as an air conditioning device, installed in a vehicle.

1. A vehicle fluid heating device comprising:
a tank that internally includes a flow path that guides a fluid;
a heater that is disposed to sandwich the tank and heats the fluid by heating the tank; and
at least one control element that controls the heater, wherein
the tank includes front and rear surfaces where the heater is disposed, and a side surface different from the front and rear surfaces, and
the at least one control element is disposed on the side surface of the tank.

2. The vehicle fluid heating device according to claim 1, further comprising:
a contact layer that is planar and is disposed on the side surface of the tank, wherein
the contact layer is interposed between the tank and the at least one control element.

3. The vehicle fluid heating device according to claim 2, wherein
the at least one control element is disposed in close contact with the side surface via the contact layer.

4. The vehicle fluid heating device according to claim 1, wherein
the flow path includes a supply port through which the fluid is to be supplied into the tank from outside, and a discharge port through which the fluid that has traveled through the flow path in the tank is to be discharged outward,
a plurality of control elements are disposed at the tank, each of the plurality of control elements being the at least one control element, and
of the plurality of control elements, a control element with a larger amount of heat generation is disposed closer to the supply port.

5. The vehicle fluid heating device according to claim 1, wherein
the flow path includes a supply port through which the fluid is to be supplied into the tank from outside, and a discharge port through which the fluid that has traveled through the flow path in the tank is to be discharged outward,
a plurality of control elements are disposed at the tank, each of the plurality of control elements being the at least one control element,
the plurality of control elements include a first element that controls the heater and a second element that controls the heater when the first element fails, and
the first element is disposed closer to the supply port than the second element is.

6. The vehicle fluid heating device according to claim 1, wherein
the heater is disposed in a different area corresponding to the flow path and excluding an area corresponding to a region between the at least one control element and the flow path, or has a lower heat generation density in the area than a heat generation density in the different area.

7. The vehicle fluid heating device according to claim 1, wherein
the tank includes a heating region where the heater is disposed and a non-heating region where the heater is not disposed, and
the non-heating region is located between the heating region and the at least one control element.

8. The vehicle fluid heating device according to claim 1, wherein
the heater includes a first area that heats a portion of the flow path farther from the at least one control element and a second area that heats a portion of the flow path closer to the at least one control element, and
the at least one control element individually controls the first area and the second area.

9. The vehicle fluid heating device according to claim 1, wherein
a plurality of control elements are disposed at the tank, each of the plurality of control elements being the at least one control element, and
the plurality of control elements are disposed to sandwich the flow path.

10. The vehicle fluid heating device according to claim 1, wherein
the flow path includes a first flow path and a second flow path into which the fluid is to flow from a supply port of the tank, and a third flow path into which the fluid is to flow from at least one of the first flow path or the second flow path,
the second flow path is a flow path that bypasses the first flow path, and
the at least one control element is disposed on the side surface to be in contact with the second flow path.

11. The vehicle fluid heating device according to claim 10, wherein
the heater includes a third area corresponding to the first flow path and the third flow path, and a fourth area corresponding to the second flow path, and
the heater has a lower heat generation density in the fourth area than a heat generation density in the third area.

12. The vehicle fluid heating device according to claim 10, wherein
the heater includes a third area corresponding to the first flow path and the third flow path, and a fourth area corresponding to the second flow path, and
the at least one control element individually controls the third area and the fourth area.

13. The vehicle fluid heating device according to claim 10, wherein
a cross-sectional area of the second flow path is smaller than a cross-sectional area of the first flow path.

14. The vehicle fluid heating device according to claim 10, wherein
a plurality of control elements are disposed at the tank, each of the plurality of control elements being the at least one control element, and
among the plurality of control elements, a control element with a largest amount of heat generation is disposed alone on the side surface to be in contact with the second flow path.

15. The vehicle fluid heating device according to claim 10, further comprising:
a temperature detector that detects a temperature of the at least one control element;
a valve that is disposed in the tank and used for controlling an inflow amount of the fluid flowing into the second flow path; and
a controller that controls opening and closing of the valve, wherein
the controller closes the valve when the temperature detected by the temperature detector is less than a first predetermined value, and opens the valve when the temperature detected by the temperature detector is greater than or equal to the first predetermined value.

16. The vehicle fluid heating device according to claim 10, further comprising:
a temperature detector that detects a temperature of the tank;
a valve that is disposed in the tank and used for controlling an inflow amount of the fluid flowing into the second flow path; and
a controller that controls opening and closing of the valve, wherein
the controller closes the valve when the temperature detected by the temperature detector is less than a first predetermined value, and opens the valve when the temperature detected by the temperature detector is greater than or equal to the first predetermined value.

17. The vehicle fluid heating device according to claim 10, wherein
the tank has a cavity between the first flow path and the second flow path, and
the at least one control element is disposed in the cavity to be in contact with the second flow path.

18. The vehicle fluid heating device according to claim 1, further comprising:
a temperature detector that detects a temperature of the at least one control element, wherein
the temperature detector is attached to the at least one control element.

19. The vehicle fluid heating device according to claim 1, further comprising:
a temperature detector that detects a temperature of the at least one control element, wherein
the temperature detector is attached to the side surface to be adjacent to the at least one control element, and
the at least one control element controls the heater to stop heating the tank when the temperature detected by the temperature detector is greater than or equal to a second predetermined value.

20. The vehicle fluid heating device according to claim 1, wherein
a plurality of control elements are disposed at the tank, each of the plurality of control elements being the at least one control element,
the vehicle fluid heating device further comprises a first temperature detector and a second temperature detector that each detect a temperature of the plurality of control elements,
the plurality of control elements include a first control element with a largest amount of heat generation, a second control element with a next largest amount of heat generation after the first control element, and a third control element with a smaller amount of heat generation than the first control element or the second control element,
the first temperature detector is disposed on the side surface to be adjacent to the first control element and the third control element,
the second temperature detector is disposed on the side surface to be adjacent to the second control element and the third control element, and
the at least one control element controls the heater to stop heating the tank when the temperature detected by at least one of the first temperature detector or the second temperature detector is greater than or equal to a second predetermined value.
